(19) United States
(12) Patent Application Publication
(10) Pub. No.: US 2026/0237604 A1
(43) Pub. Date: Aug. 13, 2026

(54) System and Method for Atomic Layer Etching Using an Added Sidewall Coil in Proximity to a Chuck for Substrate Edge Uniformity Control

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 19/048,950

(22) Filed: Feb. 9, 2025

(51) Int. Cl. H01J 37/32

(52) U.S. Cl. CPC H01J 37/3211; H01J 37/32146; H01J 37/32467; H01J 37/32697; H01J 37/32715; H01J 2237/3341

(57) ABSTRACT

Disclosed herein are systems and methods for an atomic layer etching (ALE) process that includes a surface modification step followed by a sputtering step. An enhanced transformer coupled plasma (TCP) source incorporating an additional sidewall coil positioned near the chuck is utilized to increase plasma density during the surface modification step and to provide improved control over ion density, energy, and angular distribution, particularly around the substrate edge during the sputtering step.

### FIELD OF THE INVENTION

The present invention relates to atomic layer etching (ALE) processes and systems. More specifically, the invention pertains to an ALE process system utilizing a transformer coupled plasma (TCP) source with a supplemental sidewall coil positioned near a chuck to improve control of ions around the edge of a substrate during a sputtering step of the ALE process.

### BACKGROUND OF THE INVENTION

ALE is a precise etching technique that removes material in a layer-by-layer manner through alternating steps of surface modification and sputtering. In some implementations, the surface modification step introduces reactive species to chemically modify the topmost atomic layers of the substrate, followed by a sputtering step that removes the modified layer using energetic ions. This alternating cycle is repeated multiple times to achieve the desired etch depth with high precision.

Despite its advantages in selectivity and atomic-scale control, ALE is slow due to the use of different gases for the surface modification and the sputtering steps. In some implementations, one approach to improving throughput is to use a smaller process chamber, which reduces the volume of gas to be exchanged between steps, thereby accelerating process transitions. However, implementing ALE in small process chambers presents significant challenges, particularly in maintaining plasma uniformity.

In some embodiments, a conventional transformer coupled plasma (TCP) source, which includes a center coil, and an edge coil positioned atop a dielectric window, is used to generate plasma. While such a configuration is effective in larger chambers, it may not provide sufficient plasma uniformity in a small chamber, particularly during the sputtering step. In some implementations, the limited plasma diffusion distance in a small chamber can result in non-uniform ion density and angular distribution, leading to inconsistent etching depth and profiles.

Accordingly, there is a need for an improved plasma source configuration that enables ALE in smaller chambers while maintaining plasma uniformity, particularly during the sputtering step.

### SUMMARY

In some embodiments, a system and method for ALE incorporate an additional sidewall coil to supplement a conventional TCP source, addressing the challenge of plasma uniformity in small process chambers. The sidewall coil, positioned along the process chamber sidewall near a chuck holding a substrate, enhances plasma characteristics by improving control over ion density, energy, and angular distribution at the edge of the substrate during the sputtering step. Additionally, in the surface modification step, the sidewall coil increases radical density, facilitating a more efficient and uniform modification of the substrate surface.

In some implementations, the sidewall coil operates independently from the center and edge coils of the TCP source, receiving RF power at a distinct frequency from a dedicated RF power generator. This independent control allows for optimized plasma conditions tailored to each ALE step. In the surface modification step, enhanced radical density promotes more effective chemical modification of the surface. During the sputtering step, improved ion control ensures consistent etching, particularly at the substrate edge, where non-uniformity is more pronounced in small chambers.

By integrating the sidewall coil into the ALE process system, in some implementations, plasma uniformity is significantly improved, enabling ALE in smaller chambers while maintaining etch consistency and process stability. The system adjusts RF power parameters to optimize radical distribution, ion energy, and angular spread, ensuring precise and repeatable ALE cycles.

Accordingly, the disclosed system and method enhance control over plasma characteristics, particularly in small process chambers, improving etch uniformity, throughput, and overall process efficiency.

### BRIEF DESCRIPTIONS OF THE DRAWINGS

The clarity of the embodiments is enhanced by referring to the following description in conjunction with the accompanying drawings:

FIG. 1: Illustrates an exemplary ALE process system utilizing a TCP source with an added sidewall coil positioned near the chuck.

FIG. 2: Presents a flowchart of an ALE process employing the TCP source with the added sidewall coil, detailing the sequential steps of surface modification and sputtering, along with plasma control mechanisms.

### DETAILED DESCRIPTIONS

To foster a comprehensive understanding, this description elaborates on specific implementations of the current invention. While specific details are provided for clarity, modifications and variations that align with the following claims are deemed acceptable. Some established procedures and components are selectively described to highlight the unique aspects of the invention.

### Terms Used

Atomic Layer Etching (ALE): A plasma-based etching process that removes material layer-by-layer through alternating surface modification and sputtering steps, enabling precise etch control at the atomic scale.

Process Chamber: A vacuum-sealed enclosure, designed to maintain controlled plasma conditions, gas flow, and chamber pressure.

Transformer Coupled Plasma (TCP) Source: A plasma generation system consisting of center and edge RF coils positioned above a dielectric window of a vacuum process chamber, which induces plasma through electromagnetic field within the chamber.

Chuck: A substrate holder that secures the wafer during processing. In some implementations, the chuck may be an electrostatic chuck (ESC) or a vacuum chuck, which may also receive RF bias power to control ion energy and directionality.

Gas Distribution Unit: A component that introduces process gases into the process chamber. In some implementations, the gas distribution unit may be a showerhead or injector, which can include separate channels for different process gases used in surface modification and sputtering steps.

Sidewall Coil: One or more inductively coupled RF coils positioned along the chamber sidewall near a chuck holding a substrate. The sidewall coil assists in radical generation during the surface modification step and enhances control over ion density, energy, and angle during the sputtering step, particularly at the edge of the substrate.

RF Power Generator: A power supply unit that delivers radio frequency (RF) power at different frequencies to sustain and control plasma characteristics.

Resonator: An impedance-matching component that optimizes power transfer between RF generators and the process chamber.

Tailored Waveform Generator: A device that generates the bias voltage waveform applied to the chuck, optimizing ion energy distribution.

Surface Modification Step: The first half of an ALE cycle, where radicals in the plasma chemically react with the substrate surface, forming a modified layer that is subsequently removed during the sputtering step. The process is typically self-limiting, ensuring precise material removal.

Sputtering Step: The second half of an ALE cycle, where energetic ions physically remove the modified layer, completing one etching cycle with controlled material removal.

System Controller: A computing system that regulates process parameters, including RF power levels, gas flow rates, pulsing schemes, and bias voltages, ensuring precise ALE process execution and etch uniformity.

Pulsing Scheme: A method of RF power modulation that applies timed pulses to control plasma ignition, ion energy, and radical generation.

Bias Voltage: An electrical potential applied to the chuck to control ion energy and directionality in the plasma.

Process Gas: A gas introduced into the process chamber during ALE cycles. In some implementations, the first process gas, such as chlorine, is used in the surface modification step, while an inert gas, such as argon, is used during the sputtering step to assist in layer removal.

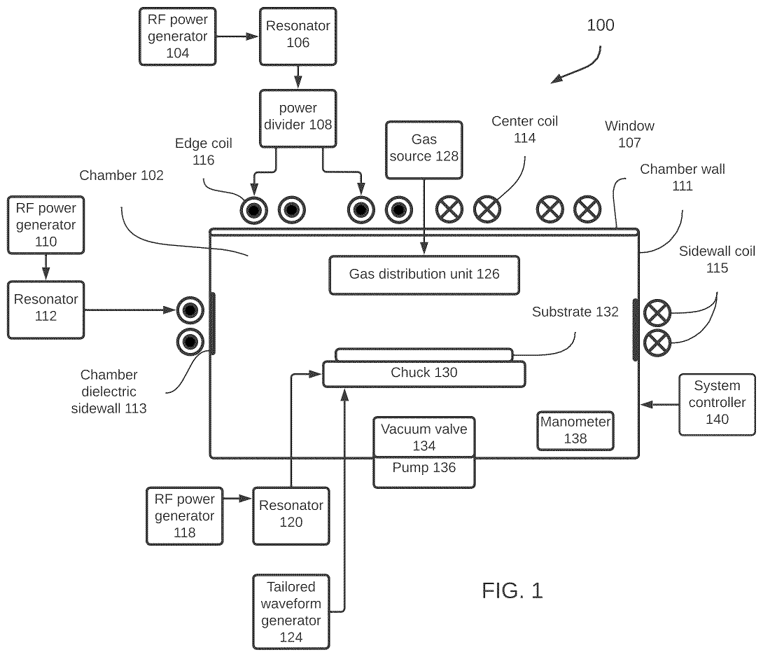

FIG. 1 illustrates an exemplary ALE process system, denoted as 100. The process system 100 includes a process chamber 102, which is configured to conduct plasma-based processes within a vacuum environment. The process chamber 102 is enclosed by a chamber wall 111, which includes a sidewall or a portion of the sidewall, labelled as 113, constructed from a dielectric material such as quartz or ceramic.

The process system 100 further includes a TCP source comprising a center coil 114 and an edge coil 116. These coils are concentrically arranged atop a window 107, which is made of a dielectric material like quartz or ceramic. The outer boundary of the edge coil 116 is positioned a short distance from the external surface of the sidewall ranging from 0 to 5 cm.

In one implementation, the center coil 114 and the edge coil 116 are driven by a single RF power generator 104 via a resonator 106. A power divider 108 allocates RF power from the RF power generator 104 between the coils. The resonator 106 matches the impedance of the RF power generator 104 to the plasma impedance while considering transmission line effects. The RF power generator 104 supplies RF power ranging from 50 to 5000 watts at a frequency selected from 13.56 MHz, 2 MHz, 1 MHz, and 400 kHz. The RF power may also be pulsed according to a pulsing scheme with a frequency range of 100 Hz to 100 kHz.

In another implementation (not shown in FIG. 1), the center coil 114 and the edge coil 116 are driven by separate RF power generators via independent resonators, providing additional flexibility in selecting frequencies and pulsing schemes for each coil. For example, the center coil 114 receives an RF power at 13.56 MHz while the edge coil receives an RF power at 1 MHz.

The process system 100 further includes an added sidewall coil 115, which receives RF power from an RF power generator 110 via a resonator 112. The sidewall coil 115 is positioned along the portion of the external surface of the process chamber sidewall 113, which is made of a dielectric material such as quartz or ceramic to allow the electromagnetic field to penetrate into the interior of the process chamber 102. The sidewall coil 115 is positioned at a vertical position with a short distance from the surface of a chuck 130.

The chuck 130 is used to hold a substrate 132 during processing, which may be an electrostatic chuck (ESC) or a vacuum chuck. The sidewall coil 115 may consist of a single or multiple turns, with its lower boundary positioned 0 to 4 cm from the surface of the chuck 130, depending on size of the process chamber 102.

The RF power generator 110 supplies RF power ranging from 50 to 1000 watts at a frequency selected from 13.56 MHz, 2 MHz, 1 MHz, 400 kHz, or 100 kHz. The RF power may also be pulsed according to a pulsing scheme with a frequency range of 100 Hz to 100 kHz. In another implementation, the RF power generator 104 may use the power divider 108 to allocate a portion of the RF power to the sidewall coil 115.

The ALE process involves alternating between a surface modification step and a sputtering step. During the surface modification step, the sidewall coil 115 assists the center and edge coils (114, 116) in increasing plasma density. Additionally, the sidewall coil 115 improves the uniformity of radical distribution within the process chamber 102.

During the sputtering step, the sidewall coil 115, powered by the RF power generator 110, generates plasma along the internal surface of the sidewall of the process chamber 102. The plasma density can be adjusted based on process requirements and chamber conditions. The sidewall coil 115 helps control ion density, energy, and angular distribution at the edge of the substrate 132, which is particularly critical when the plasma volume of the process chamber 102 is below 10 liters. In small process chambers, ions generated by the TCP source (center and edge coils) may not have sufficient diffusion distance to achieve the required uniformity.

To increase ion energy during the sputtering step, the chuck 130 receives RF power from an RF power generator 118 via a resonator 120. The RF power generator 118 typically operates at a low frequency to enhance ion energy and achieve better directionality. The frequency can be selected from 2 MHz, 1 MHz, 400 kHz, or 100 kHz, and The RF power may be pulsed according to a pulsing scheme with a frequency range of 100 Hz to 100 kHz. Some pulsing schemes may be synchronized, while others may include specific timing controls.

The gas distribution unit 126 receives process gases from a gas source 128 and distributes them into the process chamber 102. The gas distribution unit may be a showerhead or an injector. When a showerhead is used, it may also function as the window 107, isolating the process chamber 102. If an injector is used, the window 107 must include an opening to accommodate the injector, which must be sealed adequately to maintain the vacuum environment of the process chamber 102.

In some implementations, the showerhead may include two separate conduits for the first and second process gases used in the surface modification and sputtering steps, respectively. Additionally, the gas distribution unit 126 may include side injection mechanisms from the sidewall of the process chamber 102 in some implementations. The gas source 128 includes a gas box, various valves, and mass flow controllers (MFCs).

The chuck 130 supports the substrate 132, which is typically a silicon wafer. Process gases, including reaction by-products, are evacuated from the process chamber 102 by a pump 136. A vacuum valve 134, located upstream of the pump, regulates the gas removal rate. The evacuated gases are directed to an exhaust via an exhaust line (not shown in FIG. 1). The chamber pressure is controlled by balancing gas injection and removal rates, with a proportional-integral-derivative (PID) control loop adjusting the pressure based on readings from a manometer 138.

The operations of the process system 100 are coordinated by a system controller 140, which comprises a computer and various software modules.

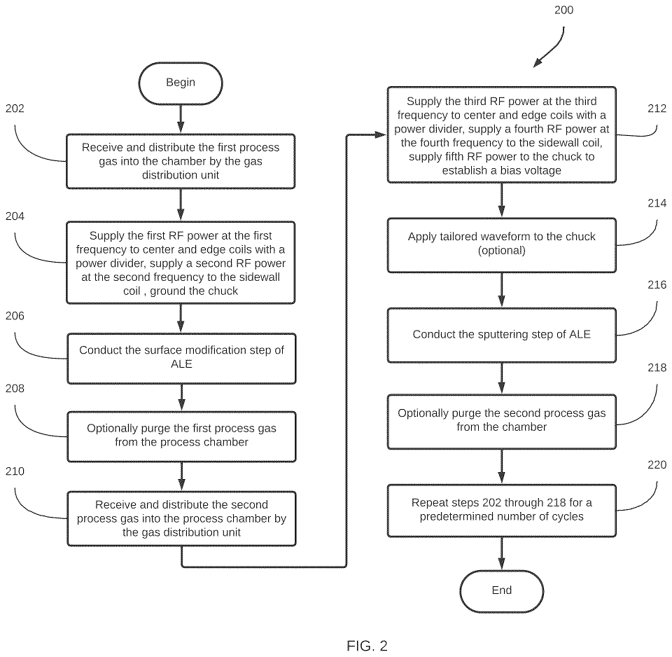

FIG. 2 illustrates a flowchart for an ALE process using the process system 100.

The process 200 begins with step 202, where the system controller 140 instructs the gas distribution unit 126 to receive a first process gas, such as chlorine, from the gas source 128. The first process gas is then distributed into the process chamber 102.

In step 204, the center coil 114 and edge coil 116 receive a first RF power according to a predetermined division at a first frequency from RF power generator 104 via resonator 106. The first frequency may be a frequency selected from a group comprising 13.56 MHz, 2 MHz, 1 MHz, and 400 kHz with a power level ranging from 50 to 5000 watts. Additionally, a second RF power at a second frequency may be supplied to the sidewall coil 115 from RF power generator 110 via resonator 112. The second frequency may be selected from a group comprising 13.56 MHz, 2 MHz, 1 MHz, 400 kHz, and 100 kHz, with a power level ranging from 50 to 1000 watts. the RF power may also be pulsed with a frequency ranged from 100 Hz to 100 kHz. During this step, the chuck 130 is grounded to minimize ion bombardment.

In step 206, the surface modification step is performed, where radicals in the plasma react with the substrate 132, forming a modified layer with self-limiting characteristics. The exposure duration is controlled to balance process performance and productivity, with a preferred exposure time of less than 200 milliseconds.

In step 208, the first process gas may optionally be purged using an inert gas such as nitrogen.

In step 210, the gas distribution unit 126 receives and distributes a second process gas, such as argon, into the process chamber 102.

In step 212, the center coil 114 and edge coil 116 receive a third RF power at a third frequency from RF power generator 104 via resonator 106. The third frequency may be selected from the group comprising 13.56 MHz, 2 MHz, 1 MHz, and 400 kHz with a power level ranging from 50 to 5000 watts. Additionally, RF power generator 110 supplies a fourth RF power at a fourth frequency to the sidewall coil 115. The fourth frequency may be selected from a group comprising 2 MHz, 1 MHz, 400 kHz, and 100 kHz, with a power level ranging from 50 to 1000 watts. The RF power may be pulsed with a frequency ranging from 100 Hz to 100 kHz. The chuck 130 receives a fifth RF power from RF power generator 118 via resonator 120 to establish a bias voltage ranging from 50 to 5000 volts.

In step 214, a tailored waveform generator 124 may optionally be applied to improve ion energy distribution.

In step 216, the sputtering step is performed, where ions in the plasma remove the modified layer. The bias voltage may range from 50 to 5000 volts, and the RF power and tailored waveform can be pulsed according to a predetermined pulsing scheme.

In step 218, the second process gas may optionally be purged using nitrogen.

In step 220, steps 202 to 218 are repeated for a predetermined number of cycles to complete the ALE process. The number of cycles is adjusted based on the required etch depth and material removal rate. The system controller 140 dynamically manages process parameters, including RF power levels, pulsing schemes, and gas flow rates, to ensure consistent etch performance and process uniformity.

By leveraging independent plasma sources and precise control over plasma characteristics, the process system 100, with its TCP source supplemented by the sidewall coil, enhances ALE processes, particularly for small process chambers where plasma uniformity and control are more challenging.

1. A process system, comprising:
a process chamber configured to operate under vacuum conditions, comprising a sidewall that includes at least a portion constructed from a dielectric material;
a chuck positioned within the process chamber, configured to support a substrate during a plasma-based process;
a gas distribution unit configured to receive and distribute process gases into the process chamber;
a first RF power generator configured to supply a first RF power to a center coil and an edge coil which are arranged concentrically atop the process chamber;
a second RF power generator configured to supply a second RF power to a sidewall coil positioned along the portion of the sidewall constructed from the dielectric material; and
a bias unit comprising a third RF power generator and/or a tailored waveform generator wherein the bias unit is coupled to the chuck.

2. The system of claim 1, wherein the outer boundary of the edge coil is positioned within a distance from the external surface of the chamber sidewall, wherein the distance ranges from 0 to 5 cm.

3. The system of claim 1, wherein the dielectric material includes quartz and/or ceramic.

4. The system of claim 1, wherein the first RF power generator is coupled to the center coil and the edge coil via a power divider configured to divide the RF power between the coils.

5. The system of claim 1, wherein the first RF power is at a frequency selected from a group comprising 13.56 MHz, 2 MHz, 1 MHz, and 400 kHz.

6. The system of claim 1, wherein the first RF power is with a power level ranging from 50 to 5000 watts.

7. The system of claim 1, wherein the first RF power generator comprises two RF power generators, supplying RF power to the center coil and the edge coil independently.

8. The system of claim 7, wherein the two RF power generators operate at the same frequency or at two different frequencies selected from a group comprising 13.56 MHz, 2 MHz, 1 MHz, and 400 kHz.

9. The system of claim 1, wherein the sidewall coil comprises a single turn or multiple turns.

10. The system of claim 1, wherein the lower boundary of the sidewall coil is positioned at a distance from the surface of the chuck ranging from 0 to 4 cm.

11. The system of claim 1, wherein the second RF power is at a power level from 50 to 1000 watts and a frequency selected from a group comprising 13.56 MHz, 2 MHz, 1 MHz, 400 kHz, and 100 kHz.

12. The system of claim 1, wherein the first and second RF power generators are combined into a single RF power generator, and a power divider is used to allocate RF power into the center, the edge and the sidewall coil.

13. The system of claim 1, wherein the first, second and third RF powers are pulsed according to respective pulsing schemes, wherein selected pulsing schemes may be synchronized.

14. The system of claim 1, wherein the process system is an ALE process system for an ALE process configured to perform an ALE process comprising a surface modification step and a sputtering step.

15. The system of claim 1, wherein the sidewall of the process chamber is fully constructed from the dielectric material.

16. A method for processing a substrate using an ALE process, comprising:
a. providing a process chamber under vacuum conditions, wherein the process chamber includes a TCP source comprising a center coil and an edge coil positioned atop the process chamber, a sidewall coil positioned along external surface of the sidewall of the process chamber, and a chuck coupled to a bias unit;
b. receiving and distributing a first process gas into the process chamber via a gas distribution unit;
c. supplying a first RF power at a first frequency to the center and the edge coils via a power divider, supplying a second RF power at second frequency to the sidewall coil, and grounding the chuck;
d. conducting a surface modification step of the ALE process;
e. optionally purging the first process gas from the process chamber;
f. receiving and distributing a second process gas into the process chamber via the gas distribution unit;
g. supplying a third RF power at a third frequency to the center and edge coil via the power divider, supplying a fourth RF power at a fourth frequency to the sidewall coil, supplying a fifth RF power to the chuck to establish a bias voltage;
h. optionally applying a tailored waveform generator to the chuck;
i. conducting a sputtering step of the ALE process;
j. optionally purging the second process gas from the process chamber; and
k. repeating steps (b) through (j) for a predetermined number of cycles to complete the ALE process.

17. The method of claim 16, further comprising pulsing one or more RF powers according to predetermined pulsing schemes during the surface modification step.

18. The method of claim 17, wherein the predetermined pulsing schemes include synchronizing selected pulsing schemes.

19. The method of claim 16, further comprising pulsing one or more RF powers according to predetermined pulsing schemes during the sputtering step.

20. The method of claim 19, wherein predetermined pulsing schemes include synchronizing selected pulsing schemes.
